(19) United States
(12) Patent Application Publication
(10) Pub. No.: US 2001/0002331 A1
(43) Pub. Date: May 31, 2001

(54) Method for fabricating multi-layered wiring

(75) Inventor: Koji Miyata, Mie (JP)

Correspondence Address: Ronald P. Kananen, Esq., RADER, FISHMAN & GRAUER, The Lion Building, 1233 20th Street, N.W., Suite 501, Washington, DC, 20036, US

(73) Assignee: Sony Corporation

(21) Appl. No.: 09/725,060

(22) Filed: Nov. 29, 2000

(30) Foreign Application Priority Data
Nov. 30, 1999 (JP) P11-339279

(51) Int. Cl. H01L 21/4763; H01L 21/311

(52) U.S. Cl. 438/618; 438/637; 438/639; 438/700; 438/701

(57) ABSTRACT

A method for fabricating dual-damascene structure based on the double-layered mask process, in which the etching mask is successfully prevented from being recessed thereby to improve the process accuracy is provided. The method is such that for fabricating multi-layered wiring in which a wiring groove 22 for forming a wiring and a connection hole 21 for forming a plug for connecting such wiring filled in such wiring groove 22 and another wiring provided in the lower layer of such wiring are formed to a first and second interlayer insulating films 12, 14 using a first mask 15 and a second mask 16 provided in the upper layer of such first mask 15, wherein an opening 17 is formed to the second mask 16, and on the lateral wall of such opening 17 a sidewall 19 made of a material, which is higher in etching resistance than the second mask 16, is formed.

### BACKGROUND OF THE INVENTION

1. Field of the Invention

The present invention relates to a method for fabricating multi-layered wiring and in more detail to such method having a step for forming a dual-damascene structure using two layers of hard mask.

2. Description of the Related Art

Recent needs for improved operation speed and lower power consumption of semiconductor devices are promoting development of a process technology for forming a dual-damascene structure to a low-k material (a material having a low dielectric constant) layer. In the dual-damascene structure, wiring grooves and connection holes (via holes) are previously formed to an interlayer insulating film and a conductive material is simultaneously filled in both of such wiring grooves and via holes, so that the process is advantageous in reducing the production cost as compared with that for the single-damascene process in which via holes and wiring grooves are filled with conductive material in separate process steps. In general, forming of the wiring grooves and via holes to the interlayer insulating film requires a resist removal process to be repeated twice. Many of low-k material are, however, likely to degrade in the resist removal process, and thus it is necessary to avoid exposure of the low-k material during such process. It is therefore important to consider the processes sequence in the dual-damascene process in which low-k material is used for the interlayer insulating film.

One measure for addressing such problem relates to the double-layered hard mask process described on pages 41 to 42 of 1999 Symposium on VLSI Technology Digest of Technical Papers (U.S.A.). Three Examples of the double-layered hard mask process will serially be explained hereinafter (Conventional Examples 1 to 3).

First, the conventional Example 1 will be described referring to FIGS. 4A to 4F showing sectional views of the process steps.

As shown in FIG. 4A, on a substrate 110 on which transistors, wirings and so forth are already fabricated; a thin passivation film 111 is formed using a material, which is capable of preventing the wiring material from being diffused, such as silicon nitride or silicon carbide; a first interlayer insulating film 112 to which a via hole will be made is formed using silicon oxide; an etching stopper layer 113 is formed using silicon nitride; a second interlayer insulating film 114 to which a wiring will be made is formed using silicon oxide; an insulating lower mask 115 made of a silicon oxide film is formed; and further thereon an insulating upper mask 116 made of silicon nitride or silicon is formed.

Now in the conventional Example 1, the lower mask 115 and the second interlayer insulating film 114 are commonly made of a silicon oxide film so as to practically compose a single continuous film. While such fabrication process for obtaining the dual-damascene structure is not generally referred to as the double-layered hard mask process since the lower mask 115 and the second interlayer insulating film 114 cannot be defined as separate films, the process will be included in the double-layered hard mask process for convenience in this specification since the process can achieve effects equivalent to those in the double-layered hard mask process. The description below deals the second interlayer insulating film 114 as having the lower mask 115 included therein.

Next, a resist mask 131 used for processing a wiring groove is formed on the upper mask 116. The resist mask 131 is provided with an opening 132 in which the process for forming the wiring groove will proceed. Next as shown in FIG. 4B, the upper mask 116 is etched while being partially protected with the resist mask 131 (see FIG. 4A) thereby to form a groove pattern 117. The resist mask 131 is then removed.

Next as shown in FIG. 4C, on the upper mask 116 and the second interlayer insulating film 114 a resist mask 133 used for processing a via hole is formed. The resist mask 133 is provided with an opening 134 in which the process for forming the via hole will proceed. Next as shown in FIG. 4D, the second interlayer insulating film 114 and the etching stopper layer 113 are serially etched while being partially protected with the resist mask 133 (see FIG. 4A) thereby to form a via hole pattern 118. The resist mask 133 is then removed.

Next, as shown in FIG. 4E, the second interlayer insulating film 114 is etched using the upper mask 116 as an etching mask. Here the first interlayer insulating film 112 made of a silicon oxide film is also etched thereby to produce a wiring groove 122 and via hole 121. Next as shown in FIG. 4F, the passivation film 111 exposed within the bottom of the via hole 121 is etched. In this process, also the upper mask 116 (see FIG. 4E) made of the same kind of material is etched off.

The conventional Example 2 will now be explained referring to FIGS. 5A to 5H showing sectional views of the process steps.

First as shown in FIG. 5A, on a substrate 110 on which transistors, wirings and so forth are already fabricated; a thin passivation film 111 is formed using a material, which is capable of preventing the wiring material from being diffused, such as silicon nitride or silicon carbide; a first interlayer insulating film 112 to which a via hole will be made is formed using silicon oxide; and without providing an etching stopper layer a second interlayer insulating film 114 to which a wiring will be made is formed using silicon oxide; an insulating lower mask 115 made of a silicon oxide film is formed; and further thereon an insulating upper mask 116 made of silicon nitride or silicon is formed. Then a resist mask 131 used for processing a wiring groove is formed on the upper mask 116. The resist mask 131 is provided with an opening 132 in which the process for forming the wiring groove will proceed.

Next as shown in FIG. 5B, the upper mask 116 is etched while being partially protected with the resist mask 131 (see FIG. 5A) thereby to form a groove pattern 117. The resist mask 131 is then removed.

Next as shown in FIG. 5C, on the upper mask 116 and the lower mask 115 a resist mask 133 used for processing a via hole is formed. The resist mask 133 is provided with an opening 134 in which the process for forming the via hole will proceed. Next as shown in FIG. 5D, the lower mask 115 is etched while being partially protected with the resist mask 133 thereby to form a via hole pattern 118.

Next as shown in FIG. 5E, the above etching is further forwarded to etch the second interlayer insulating film 114 thereby to deepen the via hole pattern 118. Here the resist mask 133 (see FIG. 5D) is also etched off. Then as shown in FIG. 5F, the lower mask 115 made of a silicon oxide film is etched using the upper mask 116 as an etching mask. During such etching, the first interlayer insulating film 112 is also etched while being masked by the second interlayer insulating film 114, thereby an upper potion of the wiring groove 122 is formed to the lower mask 115 and an upper portion of a via hole 121 to the first interlayer insulating film 112.

Next as shown in FIG. 5G, the second interlayer insulating film 114 is etched using the upper mask 116 as an etching mask thereby to form the wiring groove 122. Then as shown in FIG. 5H, the passivation film 111 exposed within the bottom of the via hole 121 is etched using the lower mask 115 and the first interlayer insulating film 112 as etching masks. During such etching, the upper mask 116 (see FIG. 5G) made of the same kind of material is also etched off.

The conventional Example 3 will now be explained referring to FIGS. 6A to 6H showing sectional views of the process steps.

First as shown in FIG. 6A, on a substrate 110 on which transistors, wirings and so forth are already fabricated; a thin passivation film 111 is formed using a material, which is capable of preventing the wiring material from being diffused, such as silicon nitride or silicon carbide; a first interlayer insulating film 112 to which a via hole will be made is formed using an organic insulating material; an etching stopper layer 113 is formed using silicon oxide; a second interlayer insulating film 114 to which a wiring will be made is formed using an organic insulating material; an insulating lower mask 115 made of a silicon oxide film is formed; and further thereon an insulating upper mask 116 made of silicon nitride or silicon is formed. Then a resist mask 131 used for processing a wiring groove is formed on the upper mask 116. The resist mask 131 is provided with an opening 132 in which the process for forming the wiring groove will proceed.

Next as shown in FIG. 6B, the upper mask 116 is etched while being partially protected with the resist mask 131 (see FIG. 6A) thereby to form a groove pattern 117. The resist mask 131 is then removed.

Next as shown in FIG. 6C, on the upper mask 116 and the lower mask 115 a resist mask 133 used for processing a via hole is formed. The resist mask 133 is provided with an opening 134 in which the process for forming the via hole will proceed. Next as shown in FIG. 6D, the lower mask 115 is etched while being partially protected with the resist mask 133 thereby to form a via hole pattern 118. Further as shown in FIG. 6E, the above etching is further forwarded to etch the second interlayer insulating film 114 thereby to deepen the via hole pattern 118. Here the resist mask 133 (see FIG. 6D) is also etched off.

Then as shown in FIG. 6F, the lower mask 115 made of a silicon oxide film is etched using the upper mask 116 as an etching mask. During such etching, the etching stopper film 113 made of a silicon oxide film is also etched while being masked by the second interlayer insulating film 114, thereby an upper potion of the via hole 121 is formed to the etching stopper layer 113.

Next as shown in FIG. 6G, the second interlayer insulating film 114 made of an organic insulating material is etched using the upper mask 116 as an etching mask thereby to form the wiring groove 122. During such etching, the first interlayer insulating film 112 made of an organic insulating material is also etched thereby to form a part of the via hole 121.

Then as shown in FIG. 6H, the passivation film 111 exposed within the bottom of the via hole 121 is etched using the lower mask 115 and the etching stopper layer 113, both of which being made of a silicon oxide film, as etching masks. During such etching, the upper mask 116 (see FIG. 6G) made of a similar kind of material, i.e. silicon nitride, is also etched off.

The silicon oxide film described above can be formed with, for example, an organic SOG (Spin On Glass) film. The organic SOG film is beneficial in that being lower in dielectric constant than vapor deposited or sputtered silicon oxide film, and thus affording semiconductor devices having advanced performance. Such organic SOG film is applicable to the etching stopper layer 111 in the conventional Example 3.

Next paragraphs describe a conventional applied technology of the double-layered hard mask process, and more particularly, a technique for forming a via hole within a wiring groove in a self-aligned manner (see Advanced Metallization Conference (1999) (U.S.A.), p.163, which is so-called “self-aligned via hole process”.

FIG. 7A shows an exemplary case in which an area “V” for a via hole pattern defined on a photomask is misaligned by an amount “M” to an area “T” for a wiring groove pattern defined on a photomask. The area “V” for the via hole pattern defined on the photomask is transferred to an via hole mask 213 to form an opening 223; a second interlayer insulating film 214 and a wiring groove mask 215 are formed; then the area “T” for the wiring groove defined on the photomask is transferred to the wiring groove mask 215 to form an opening 224. Then the second interlayer insulating film 214 is etched using the wiring groove mask 215 as an etching mask, thereby to form a wiring groove 222. Further the first interlayer insulating film 212 and the passivation film 211 are etched using the via hole mask 213 as an etching mask, thereby to form a via hole 221. Thus the technique allows the via hole 221 to be formed only within the wiring groove 222 in a self-aligned manner even if a part of the opening 223 formed in the via hole mask 213 does not overlap such wiring groove 222.

Or, another possible process is such that intentionally designing the via hole pattern defined on the photomask wider than the wiring groove pattern, and forming the via hole just fitted to the wiring groove; such process may also be referred to as “self-aligned via hole process”.

FIG. 7B shows an exemplary case of “non self-aligned via process” in which an area “V” for a via hole pattern defined on a photomask is misaligned by an amount “M” to an area “T” for a wiring groove pattern defined on a photomask. The area “T” for the wiring groove pattern defined on the photomask is transferred to a wiring groove mask 215 to form an opening 224; and a second interlayer insulating film 214 is etched using the wiring groove mask 215 as an etching mask, thereby to form a wiring groove 222. Then the area “V” for the via hole pattern defined on the photomask is transferred to the via hole mask 213 to form an opening 223; and the first interlayer insulating film 212 is etched using the via hole mask 213 as an etching mask, thereby to form a via hole 221. Thus in the case of misalignment, a part of the via hole 221 is formed so as to fall outside the wiring groove 222.

The foregoing self-aligned via processes are applicable to any of the conventional Examples 1 to 3. More specifically, the process step explained referring to FIG. 4D in the conventional Example 1, the process step explained referring to FIGS. 5D and 5E in the conventional Example 2, and the process step explained referring to FIGS. 6D and 6E in the conventional Example 3 will be successful if the etching is carried out while keeping a high etching selectivity over the upper mask.

A problem, however, reside in the conventional Example 1, in which the second and first interlayer insulating films are etched using the upper mask made of silicon or silicon nitride as an etching mask, in that the upper mask is significantly eroded on its shoulder portion, which causes recession of the mask and thereby to undesirably widen the wiring groove. This is because silicon nitride or silicon used for composing the upper mask is less durable against the dry etching conditioned for etching silicon oxide film, which makes it difficult to obtain the wiring groove just in design size. In the conventional Example 1, the etching of the first interlayer insulating film of 500 nm thick resulted in the width of the wiring groove wider by 150 nm than the design size.

Also in the Conventional Example 1, the first and second interlayer insulating films may also be made of organic SOG, where the etching rate of which is approx. ⅓of that of silicon oxide under the above etching conditions. It is thus necessary to increase the etching time, which results in further widening of the wiring groove.

In the conventional Example 2, the lower mask and the first interlayer insulating film both made of silicon oxide are etched using the upper mask made of silicon or silicon nitride as an etching mask. A problem again arises in such process that the upper mask is significantly eroded on its shoulder portion, which causes recession of the mask and thereby to undesirably widen the wiring groove. This is because silicon nitride or silicon used for composing the upper mask is less durable against the dry etching conditioned for etching silicon oxide film, which makes it difficult to obtain the wiring groove just in designed size. In the conventional Example 2, the etching of the first interlayer insulating film of 500 nm thick resulted in the width of the wiring groove wider by 150 nm than the designed size.

Also in the conventional Example 2, the first and second interlayer insulating films may also be made of the organic SOG, where the etching rate of which is approx. ⅓of that of silicon oxide under the above etching conditions. It is thus necessary to increase the etching time, which results in further widening of the wiring groove.

In the conventional Example 3, the lower mask made of silicon oxide is etched using the upper mask made of silicon or silicon nitride as an etching mask. A problem still again arises in such process that the upper mask is significantly eroded on its shoulder portion, which causes recession of the mask and thereby to undesirably widen the wiring groove. This is because silicon nitride or silicon used for composing the upper mask is less durable against the dry etching conditioned for etching silicon oxide film, which makes it difficult to obtain the wiring groove just in designed size. In the conventional Example 3, a material to be etched is only the lower mask of 200 nm thick, and increase in the width of the wiring groove is limited to as small as 50 nm. It is, however, judged as process failure for the wiring groove of a generation requiring fine metallization, since the above widening largely exceeds an allowable range of, for example, 20 nm.

Also in the conventional Example 3, the lower mask or the intermediate etching stopper layer may also be made of organic SOG, where the etching rate of which is approx. ⅓of that of silicon oxide under the above etching conditions. It is thus necessary to increase the etching time, which results in further widening of the wiring groove.

As has been described in the above, the conventional Examples 1 to 3 are suffering from the poor etching durability of the upper mask. Another known method relates to composing the upper mask of 30 nm or around using a metal or metal compound known to exhibit excellent durability in the dry etching. Composing the upper mask with a metal or metal compound, however, prevents easy identification of the underlying layer in the lithography process, which obstructs the alignment. It has thus been necessary to compose the upper mask with silicon nitride or silicon despite its poor etching durability.

Another problem resides in the self-aligned via hole process, previously described referring to FIG. 7A, in that the wiring groove practically becomes wider in the interlayer insulating film than expected from the photomask, as shown in FIG. 4E, due to poor etching durability of the upper mask. The self-aligned via hole process in fact is thus hard to be carried out.

### SUMMARY OF THE INVENTION

It is therefore an object of the present invention to provide a method for fabricating multi-layered wiring capable or suppressing the recession of the etching mask during the etching for forming the wiring groove, thereby to improve the etching process accuracy.

The present invention intended for solving the foregoing problem relates to a method for fabricating multi-layered wiring in which a wiring groove for forming a wiring filled in such wiring groove and a connection hole for forming a plug for connecting such wiring and another wiring provided in the lower layer of such wiring are formed to an interlayer insulating film using a first mask and a second mask provided in the upper layer of such first mask, wherein an opening is formed to the second mask, and on the lateral wall of such opening a sidewall made of a material, which is higher in etching resistance than the second mask, is formed.

According to such method for fabricating multi-layered wiring, the sidewall composed of a material having higher etching durability over the second mask is formed on the lateral wall of the opening formed to the second mask, so that the second mask is successfully prevented from being recessed during etching for forming the wiring groove. Hence the wiring groove thus formed will not be widened beyond the design size, and the width of which will fall within the range of the design size. This allows the process margin for the width of the wiring groove and the space between adjacent wiring grooves, which have previously been set to an excessive value, to be reduced. This not only enhances the higher integration and higher performance of semiconductor devices but also upgrades process accuracy and thus improves the production yield.

### BRIEF DESCRIPTION OF THE DRAWINGS

FIGS. 1A to 1J are sectional views individually showing process steps of the method for fabricating multi-layered wiring according to Example 1 of the present invention;

FIGS. 2A to 2J are sectional views individually showing process steps of the method for fabricating multi-layered wiring according to Example 2 of the present invention;

FIGS. 3A to 3H are sectional views individually showing process steps of the method for fabricating multi-layered wiring according to Example 3 of the present invention;

FIGS. 4A to 4F are sectional views individually showing process steps of the method for fabricating multi-layered wiring according to the conventional Example 1;

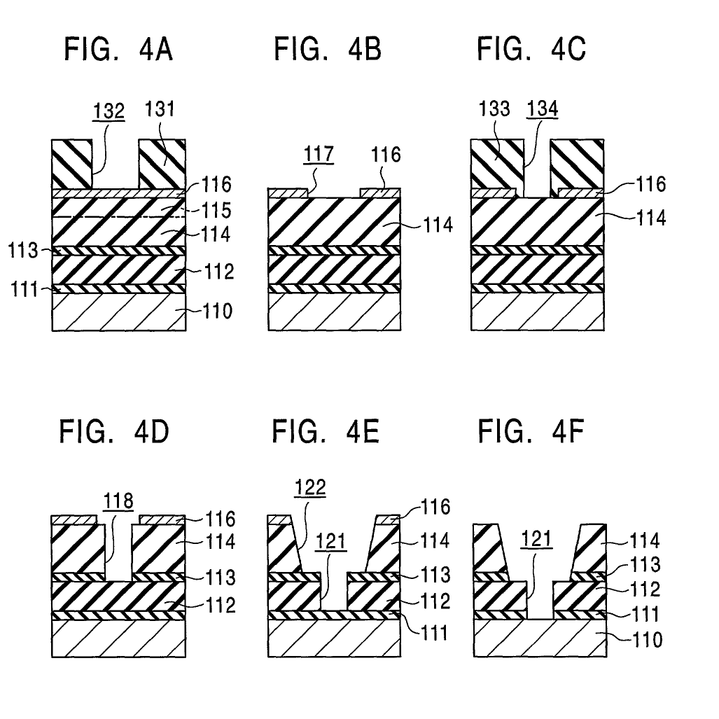

FIGS. 5A to 5H are sectional views individually showing process steps of the method for fabricating multi-layered wiring according to the conventional Example 2;

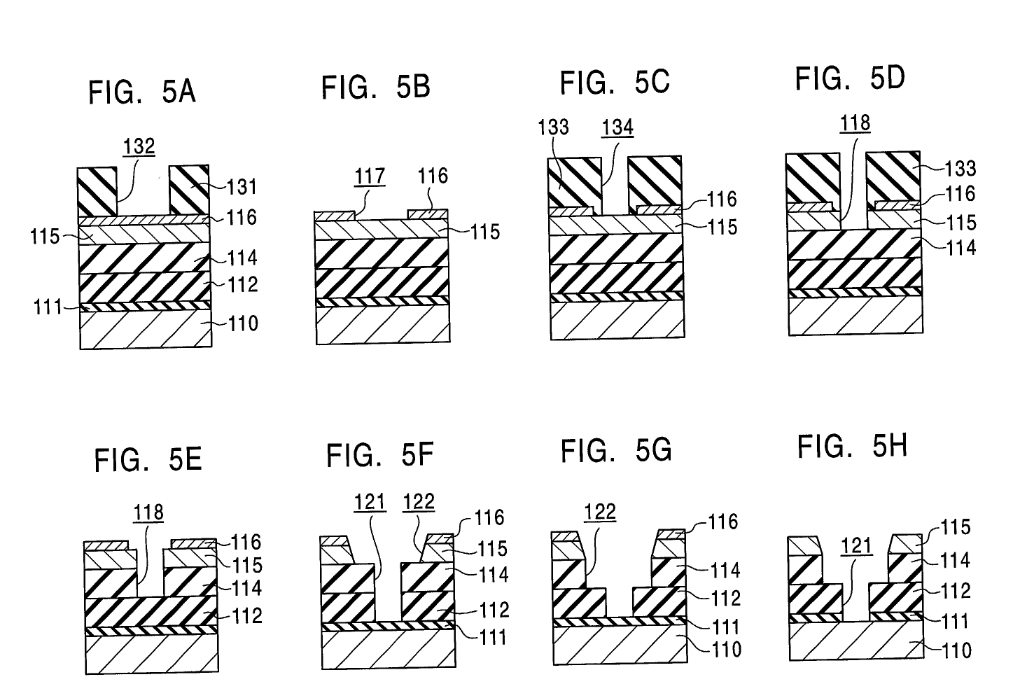

FIGS. 6A to 6H are sectional views individually showing process steps of the method for fabricating multi-layered wiring according to the conventional Example 3; and

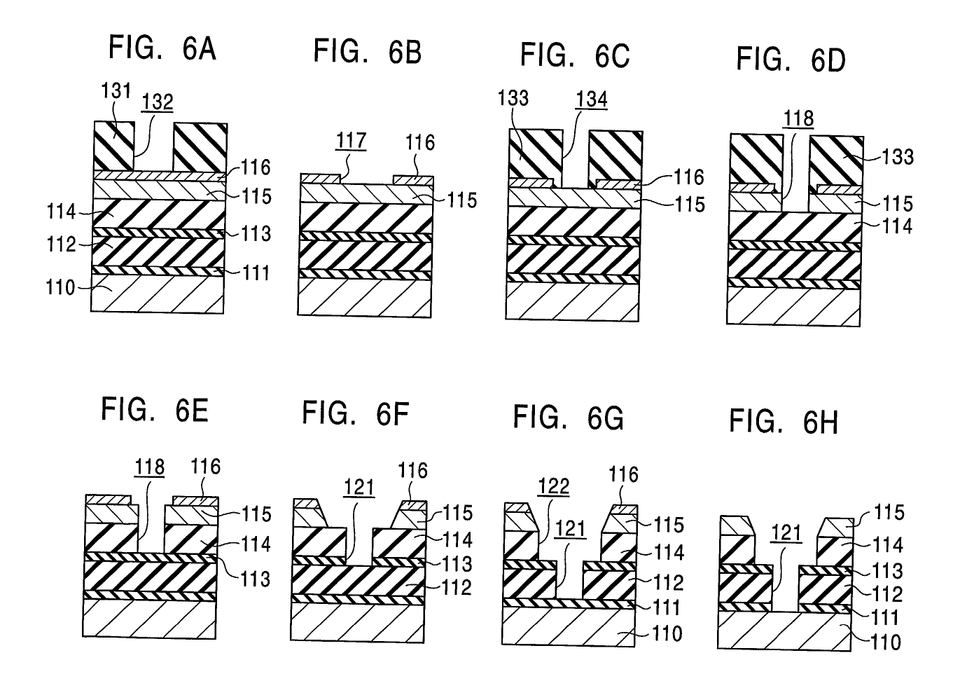

FIGS. 7A and 7B are schematic sectional views individually showing influences of misalignment occurred in the self-aligned via process and non self-aligned via hole process.

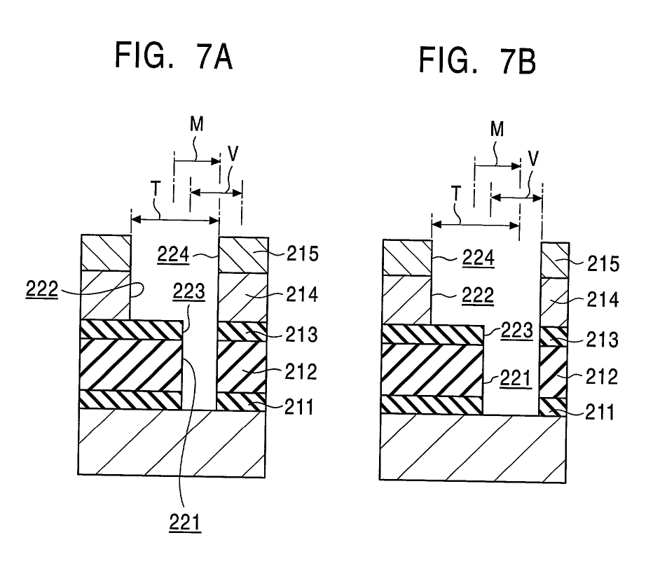

### DESCRIPTION OF THE PREFERRED EMBODIMENTS

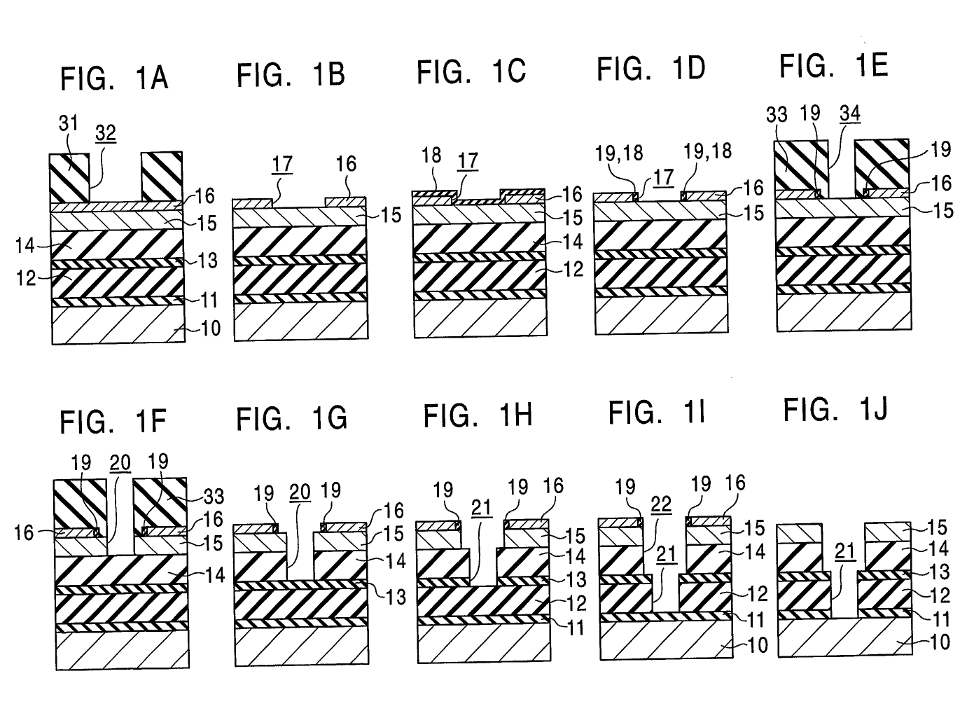

Example 1 according to the method for fabricating multi-layered wiring of the present invention will be explained hereinafter referring to FIGS. 1A to 1J individually showing the process steps.

First as shown in FIG. 1A, a substrate 10 is constituted by fabricating semiconductor devices such as transistors together with wiring, insulting film and so forth on a semiconductor substrate. On the substrate 10, a thin passivation film 11 is formed in a thickness of 50 nm using a material, capable of preventing the wiring material from being diffused, such as silicon nitride or silicon carbide. Then in a successive manner, a first interlayer insulating film 12 to which a connection hole (referred to as a via hole hereinafter) will be made is formed in a thickness of 500 nm using an organic insulating material such as polyaryl ether; an etching stopper layer 13 is formed in a thickness of 50 nm using, for example, silicon oxide; a second interlayer insulating film 14 to which a wiring groove will be made is formed in a thickness of 300 nm using an organic insulating material such as polyaryl ether; a first mask 15 is formed in a thickness of 200 nm using, for example, silicon oxide; and a second mask 16 is formed in a thickness of 100 nm using, for example, silicon nitride.

Then a resist mask 31 used for processing a wiring groove is formed on the second mask 16 according to usual resist coating and lithographic processes. The resist mask 31 is provided with an opening 32 in which the process for forming the wiring groove will proceed.

Next as shown in FIG. 1B, the second mask 16 is etched while being masked with the resist mask 31 (see FIG. 1A), thereby to form a groove pattern 17. The etching process employs a general parallel electrode plasma etching apparatus, a mixed gas of trifluoromethane (CHF₃), argon (Ar) and oxygen (O₂), and a substrate temperature of 0° C. The resist mask 31 (see FIG. 1A) is removed thereafter.

Next as shown in FIG. 1C, an insulating film 18, which will later be processed into a sidewall, is deposited in a thickness of 30 nm by a sputtering process so as to cover the top surface of the second mask 16 and the inner surface of the groove pattern 17 using, for example, tantalum nitride (TaN) which is selected as a material exhibiting an excellent durability in the etching process conditioned for etching of the first and second interlayer insulating films 12, 14. The coverage on the lateral wall achievable by the sputtering apparatus employed herein is approx. 0.5, so that the insulating film 18 is formed in a thickness of 15 nm on the lateral wall of the groove pattern 17 provided to the second mask 16.

Next as shown in FIG. 1D, the insulating film 18 is anisotropically etched so as to be remained as a sidewall 19 on the lateral wall of the groove pattern 17 provided to the second mask 16.

Then as shown in FIG. 1E, general resist coating and lithographic processes are carried out thereby to form a resist mask 33 on the second mask 16, the side wall 19 and a first mask 15. The resist mask 33 is intended for use in the formation of the via hole and thus provided with an opening 34 in which the process for forming the via hole will proceed.

Next as shown in FIG. 1F, the first mask 15 is etched while being partially masked with the resist mask 33, thereby to form a via hole pattern 20. The etching process employs a general parallel electrode plasma etching apparatus, a mixed gas of octafluorocyclobutane (c-C₄F₈), argon (Ar) and oxygen (O₂), and a substrate temperature of 0° C.

Next as shown in FIG. 1G, the etching process is further forwarded to etch the second interlayer insulating film 14 thereby to deepen the via hole pattern 20. The etching process employs a general etching apparatus of an electron cyclotron resonance (referred to as ECR hereinafter) type together with ammonia (NH₃) gas as an etching gas and a substrate temperature of −50° C. Here the resist mask 33 (see FIG. 1F) is also etched off, and the first mask 15 will serves as an etching mask in the etching process carried out hereinafter.

Next as shown in FIG. 1H, the first mask 15 made of silicon oxide is etched using the second mask 16 and the sidewall 19 as etching masks. Here the etching stopper film 13 made of silicon oxide is also etched, thereby an upper potion of the via hole 21 is formed to the etching stopper film 13. Conditions for such etching process employed here are the same as those for the etching of silicon oxide as described referring to FIG. 1F.

Next as shown in FIG. 1I, the second interlayer insulating film 14 made of an organic insulating material is etched using the second mask 16 and the sidewall 19 as etching masks, thereby to form a wiring groove 22. Here the first interlayer insulating film 12 made of an organic insulating material is also etched, thereby to form a major portion of the via hole 21. Conditions for such etching process employed here are the same as those for the etching process of the organic insulating material as described referring to FIG. 1G.

Next as shown in FIG. 1J, the passivation film 11 exposed within the bottom of the via hole 21 is etched using the first mask 15 and the etching stopper layer 13 as etching masks. Here the second mask 16 (see FIG. 1I) made of the same material is also etched and the sidewall 19 (see FIG. 1I) is also etched off. The etching process employs a general high density plasma etching apparatus together with sulfur hexafluoride (SF₆) as an etching gas and a substrate temperature of 0° C.

In the method for fabricating multi-layered wiring described in Example 1, the sidewall 19 is formed on the lateral wall of the groove pattern 17 formed to the second mask 16, so that the second mask 16 is successfully prevented by the sidewall 19 from being recessed during the etching process for forming the wiring groove 22. Hence the wiring groove 22 thus formed will not be widened beyond the designed size, and the width of which will fall within the range of the designed size.

While tantalum nitride is used as a material composing the sidewall 19 in Example 1, any material may be available provided that it has a high durability against the etching for forming the wiring groove 22. Examples of the available materials include refractory metals such as tungsten (W), titahium (Ti) and tantalum (Ta); and refractory metal compounds such as tungsten nitride (WN) and titanium nitride (TiN). Since these refractory metal base materials are popular as materials for a barrier layer for metallization materials, there is no need to introduce new apparatuses into the existing production line, which is advantageous in terms of production costs. In particular for the case that the sidewall 19 is made of tungsten (W), tantalum (Ta), tungsten nitride (WN) or tantalum nitride (TaN), such sidewall 19 can be etched off together with the second mask 16 when the etching process is proceeded with a sulfur hexafluoride (SF₆) plasma or tetrafluoromethane (CF₄) plasma described referring to FIG. 1J. Thus providing the sidewall 19 is not causative of degrading the coverage during the film formation due to residue of such sidewall 19.

In the case that the sidewall 19 is made of titanium (Ti) or titanium nitride (TiN), the removal thereof may also be performed immediately after the formation of the wiring groove 22 described referring to FIG. 1I, or after the formation of the via hole 21. An exemplary etching therefor employed a general parallel electrode RF plasma etching apparatus together with chlorine-containing gas as an etching gas, an RF power of 2 kW (13.56 MHz) and a substrate temperature of 20° C.

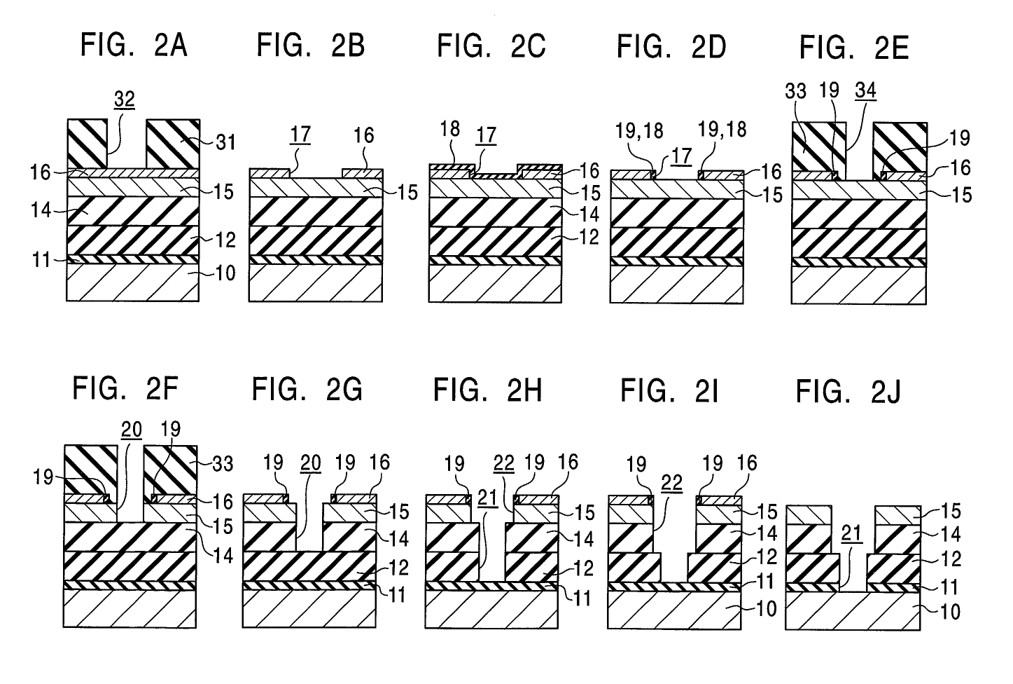

Next, Example 2 according to the method for fabricating multi-layered wiring of the present invention will be explained hereinafter referring to FIGS. 2A to 2J individually showing the process steps.

First as shown in FIG. 2A, a substrate 10 is constituted by fabricating semiconductor devices such as transistors together with wiring, insulting films and so forth on a semiconductor substrate. On the substrate 10, a thin passivation film 11 is formed in a thickness of 50 nm using a material, capable of preventing the wiring material from being diffused, such as silicon nitride or silicon carbide. Then in a successive manner a first interlayer insulating film 12 to which a connection hole (referred to as a via hole hereinafter) will be made is formed in a thickness of 500 nm using silicon oxide; a second interlayer insulating film 14 to which a wiring groove will be made is formed in a thickness of 300 nm using an organic insulating material such as polyaryl ether; a first mask 15 is formed in a thickness of 200 nm using, for example, silicon oxide; and a second mask 16 is formed in a thickness of 100 nm using, for example, silicon nitride. In this Example, the first interlayer insulating film 12 also serves as an etching stopper film.

Then a resist mask 31 used for processing a wiring groove is formed on the second mask 16 according to usual resist coating and lithographic processes. The resist mask 31 is provided with an opening 32 in which the process for forming the wiring groove will proceed.

Next as shown in FIG. 2B, the second mask 16 is etched while being masked with the resist mask 31 (see FIG. 2A), thereby to form a groove pattern 17. The resist mask 31 is removed thereafter.

Next as shown in FIG. 2C, an insulating film 18, which will later be processed into a sidewall, is deposited in a thickness of 30 nm by sputtering process so as to cover the top surface of the second mask 16 and the inner surface of the groove pattern 17 using, for example, tantalum nitride (TaN) which is selected as a material exhibiting an excellent durability in the etching process conditioned for etching of the first and second interlayer insulating films 12, 14. The coverage on the lateral wall achievable by the sputtering apparatus employed herein is approx. 0.5, so that the insulating film 18 is formed in a thickness of 15 nm on the lateral wall of the groove pattern 17 provided to the second mask 16.

Next as shown in FIG. 2D, the insulating film 18 is anisotropically etched so as to be remained as a sidewall 19 on the lateral wall of the groove pattern 17 provided to the second mask 16.

Then as shown in FIG. 2E, general resist coating and lithographic processes are carried out thereby to form a resist mask 33 on the second mask 16, the side wall 19 and a first mask 15. The resist mask 33 is intended for use in the formation of the via hole and thus provided with an opening 34 in which the process for forming the via hole will proceed.

Next as shown in FIG. 2F, the first mask 15 is etched while being partially masked with the resist mask 33, thereby to form a via hole pattern 20. The etching process employs a general parallel electrode plasma etching apparatus, a mixed gas of octafluorocyclobutane (c-C₄F₈), argon (Ar) and oxygen (O₂), and a substrate temperature of 0° C.

Next as shown in FIG. 2G, the etching process using the first mask 15 as an etching mask is further forwarded to etch the second interlayer insulating film 14 thereby to deepen the via hole pattern 20. The etching process employs a general etching apparatus of an ECR type together with ammonia (NH₃) gas as an etching gas and a substrate temperature of −50° C. Here the resist mask 33 (see FIG. 2F) is also etched off.

Next as shown in FIG. 2H, the first mask 15 made of silicon oxide is etched using the second mask 16 and the sidewall 19 as etching masks. Here the first interlayer insulating film 12 made of silicon oxide is also etched while being partially masked by the second interlayer insulating film 14, thereby an upper potion of wiring groove 22 is formed to the first mask 15 and the upper portion of the via hole 21 is formed to the first interlayer insulating film 12. Conditions for such etching process employed here are the same as those described referring to FIG. 2F.

Next as shown in FIG. 2I, the second interlayer insulating film 14 is etched using the second mask 16 and sidewall 19 as etching masks, thereby to form a wiring groove 22. Conditions for such etching process employed here are the same as those described referring to FIG. 2G.

Next as shown in FIG. 1J, the passivation film 11 exposed within the bottom of the via hole 21 is etched using the first mask 15 and the first interlayer insulating film 12 as etching masks. Here the second mask 16 (see FIG. 2I) made of the same material is also etched and the sidewall 19 (see FIG. 1I) is also etched off. The etching process employs a general high density plasma etching apparatus together with sulfur hexafluoride (SF₆) as an etching gas and a substrate temperature of 0° C.

In the method for fabricating multi-layered wiring described in Example 2, the sidewall 19 is formed on the lateral wall of the groove pattern 17 formed to the second mask 16, so that the second mask 16 is successfully prevented by the sidewall 19 from being recessed during etching for forming the wiring groove 22. Hence the wiring groove 22 thus formed will not be widened beyond the designed size, and the width of which will fall within the range of the designed size.

While tantalum nitride is used as a material composing the sidewall 19 in Example 2, any material may be available provided that it has a high durability against the etching process for forming the wiring groove 22. Examples of the available materials include refractory metals such as tungsten (W), titanium (Ti) and tantalum (Ta); and refractory metal compounds such as tungsten nitride (WN) and titanium nitride (TiN). Since these refractory metal base materials are popular as materials for a barrier layer for metallization materials, there is no need to introduce new apparatuses into the existing production line, which is advantageous in terms of production costs. In particular for the case that the sidewall 19 is made of tungsten (W), tantalum (Ta), tungsten nitride (WN) or tantalum nitride (TaN), such sidewall 19 can be etched off together with the second mask 16 when the etching process is proceeded with a sulfur hexafluoride (SF₆) plasma or a tetrafluoromethane (CF₄) plasma described referring to FIG. 2J. Thus providing the sidewall 19 is not causative of degrading the coverage during the film formation process due to residue of such sidewall 19.

In the case that the sidewall 19 is made of titanium (Ti) or titanium nitride (TiN), the removal thereof may also be performed immediately after the formation of the wiring groove 22 described referring to FIG. 2I, or after the formation of the via hole 21. An exemplary etching process therefor employed a general parallel electrode RF plasma etching apparatus together with chlorine-containing gas as an etching gas, an RF power of 2 kW (13.56 MHz) and a substrate temperature of 20° C.

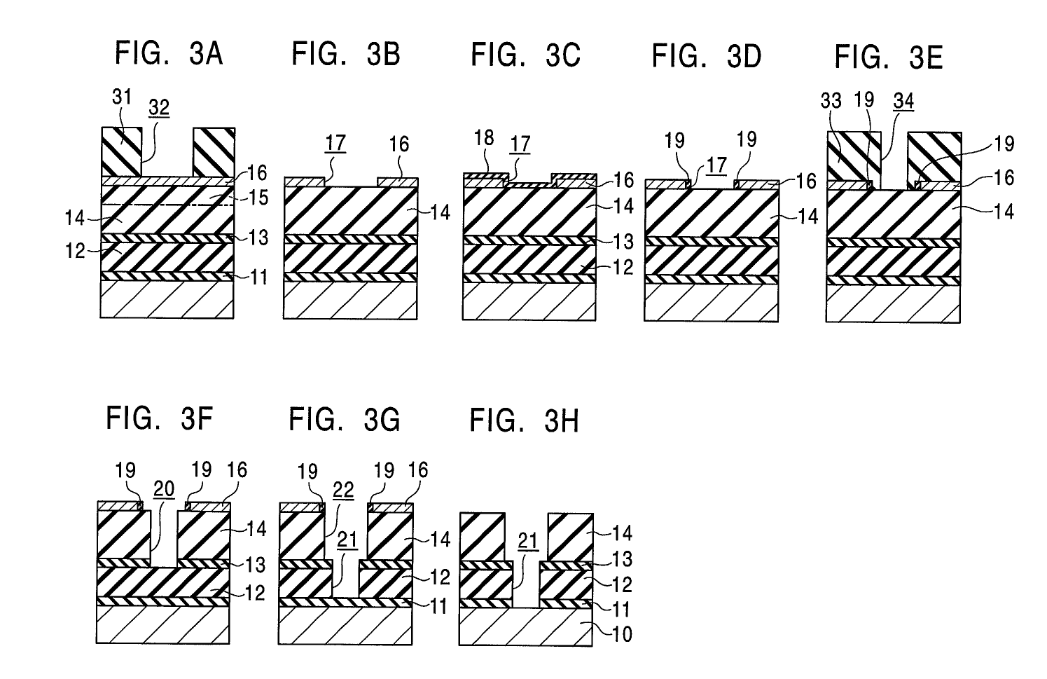

Next, Example 3 according to the method for fabricating multi-layered wiring of the present invention will be explained hereinafter referring to FIGS. 3A to 3H individually showing the process steps.

First as shown in FIG. 3A, according to the similar procedures to those explained referring to FIGS. 1A and 1B, a substrate 10 is constituted by fabricating semiconductor devices such as transistors together with wiring, insulting films and so forth on a semiconductor substrate. On the substrate 10, a thin passivation film 11 is formed in a thickness of 50 nm using a material, capable of preventing the wiring material from being diffused, such as silicon nitride or silicon carbide. Then in a successive manner a first interlayer insulating film 12 to which a a via hole will be made is formed in a thickness of 500 nm using, for example, silicon oxide; an etching stopper layer 13 is formed in a thickness of 50 nm using silicon nitride; a second interlayer insulating film 14 to which a wiring groove will be made is formed in a thickness of 300 nm using silicon oxide; a first mask 15 is formed in a thickness of 200 nm using, for example, silicon oxide; and a second mask 16 is formed in a thickness of 100 nm using, for example, silicon nitride.

Now in the Example 3, the first mask 15 and the second interlayer insulating film 14 are commonly made of a silicon oxide film so as to practically compose a single continuous film. While such fabrication process for obtaining the dual-damascene structure is not generally referred to as the double-layered hard mask process since the first mask 15 and the second interlayer insulating film 14 cannot be defined as separate films, the process will be included in the double-layered hard mask process for convenience in this specification since the process can achieve effects equivalent to those in the double-layered hard mask process. The description below deals the second interlayer insulating film 14 as having the first mask 15 included therein.

Then a resist mask 31 used for processing a wiring groove is formed on the second mask 16 according to usual resist coating and lithographic processes. The resist mask 31 is provided with an opening 32 in which the process for forming the wiring groove will proceed.

Next as shown in FIG. 3B, the second mask 16 is etched while being masked with the resist mask 31 (see FIG. 3A), thereby to form a groove pattern 17. The etching process employs a general parallel electrode plasma etching apparatus, a mixed gas of trifluoromethane (CHF₃), argon (Ar) and oxygen (O₂), and a substrate temperature of 0° C . The resist mask 31 is removed thereafter.

Next as shown in FIG. 3C, an insulating film 18, which will later be processed into a sidewall, is deposited in a thickness of 30 nm by sputtering process so as to cover the top surface of the second mask 16 and the inner surface of the groove pattern 17 using, for example, tantalum nitride (TaN) which is selected as a material exhibiting an excellent durability in the etching process conditioned for etching of the first and second interlayer insulating films 12, 14. The coverage on the lateral wall achievable by the sputtering apparatus employed herein is approx. 0.5, so that the insulating film 18 is formed in a thickness of 15 nm on the lateral wall of the groove pattern 17 provided to the second mask 16.

Next as shown in FIG. 3D, the insulating film 18 is anisotropically etched so as to be remained as a sidewall 19 on the lateral wall of the groove pattern 17 provided to the second mask 16.

Then as shown in FIG. 3E, general resist coating and lithographic processes are carried out thereby to form a resist mask 33 on the second mask 16, the side wall 19 and a first mask 15. The resist mask 33 is intended for use in the formation of the via hole and thus provided with an opening 34 in which the process for forming the via hole will proceed.

Next as shown in FIG. 3F, the second interlayer insulating film 14 and the etching stopper film 13 are serially etched while being partially masked with the resist mask 33 (see FIG. 3E), thereby to form a via hole pattern 20. The resist mask 33 is removed thereafter. The etching process employs a general parallel electrode plasma etching apparatus, a mixed gas of octafluorocyclobutane (c-C₄F₈), argon (Ar) and oxygen (O₂), and a substrate temperature of 0° C.

Next as shown in FIG. 3G, the second interlayer insulating film 14 is etched using the second mask 16 and the sidewall 19 as etching masks. Here the first interlayer insulating material 12 made of silicon oxide is also etched, thereby to form a wiring groove 22 and a via hole 21. The etching is carried out following the same procedure as described referring to FIG. 3F.

Next as shown in FIG. 3H, the passivation film 11 exposed within the bottom of the via hole 21 is etched. Here the second mask 16 (see FIG. 3G) and the etching stopper layer 13 both of which being made of the same material are also etched. The etching process employs a general high density plasma etching apparatus together with sulfur hexafluoride (SF₆) as an etching gas and a substrate temperature of 0° C.

In the method for fabricating multi-layered wiring described in Example 3, the sidewall 19 is formed on the lateral wall of the groove pattern 17 formed to the second mask 16, so that the second mask 16 is successfully prevented by the sidewall 19 from being recessed during etching process for forming the wiring groove 22. Hence the wiring groove 22 thus formed will not be widened beyond the designed size, and the width of which will fall within the range of the designed size.

While tantalum nitride is used as a material composing the sidewall 19 in Example 3, any material may be available provided that it has a high durability against the etching process for forming the wiring groove 22. Examples of the available materials include refractory metals such as tungsten (W), titanium (Ti) and tantalum (Ta); and refractory metal compounds such as tungsten nitride (WN) and titanium nitride (TiN). Since these refractory metal base materials are popular as materials for a barrier layer for metallization materials, there is no need to introduce new apparatuses into the existing production line, which is advantageous in terms of production costs. In particular for the case that the sidewall 19 is made of tungsten (W), tantalum (Ta), tungsten nitride (WN) or tantalum nitride (TaN), such sidewall 19 can be etched off together with the second mask 16, as described referring to FIG. 1J when the etching process is proceeded with a sulfur hexafluoride (SF₆) plasma or tetrafluoromethane (CF₄) plasma described referring to FIG. 3H. Thus providing the sidewall 19 is not causative of degrading the coverage during the film formation due to remaining of such sidewall 19.

In the case that the sidewall 19 is made of titanium (Ti) or titanium nitride (TiN), the removal thereof may also be performed immediately after the formation of the wiring groove 22 described referring to FIG. 3G, or after the formation of the via hole 21. The etching process therefore employs a general parallel electrode RF plasma etching apparatus together with chlorine-containing gas as an etching gas, and an RF power of 2 kW (13.56 MHz) and a substrate temperature of 20° C.

As described in Examples 1 to 3, the present invention is to suppress the recession of the second mask 16 during etching process of silicon oxide-base film. The present invention is thus in particular valuable for the case that at least one of the first interlayer insulating film 12, etching stopper layer 13, second interlayer insulating film 14 and first mask 15 is made of the organic SOG; of for the case that at least either of the first interlayer insulating film 12 or second interlayer insulating film 14 is made of silicon oxide.

What is claimed is:

1. A method for fabricating multi-layered wiring in which a wiring groove for forming a wiring and a connection hole for forming a plug for connecting said wiring filled in said wiring groove and another wiring provided in the lower layer of said wiring are formed to an interlayer insulating film using a first mask and a second mask provided in the upper layer of said first mask,
wherein an opening is formed to said second mask, and on the inner wall of said opening a sidewall made of a material, which is higher in etching resistance than said second mask, is formed.

2. The method for fabricating multi-layered wiring as claimed in claim 1, wherein said second mask is made of a silicon-base insulating material, and said sidewall is made of a refractory metal material or a refractory metal compound material.

3. The method for fabricating multi-layered wiring as claimed in claim 1, wherein said wiring groove is formed by dry etching using said second mask and said sidewall.

4. The method for fabricating multi-layered wiring as claimed in claim 1, wherein said connection hole is formed by dry etching using said first mask.

5. A method for fabricating a multi-layered wiring structure, comprising the steps of:
forming an interlayer insulating film on a multi-layered substrate;
forming a first mask on said inter-layer insulating film;
forming a second mask on said first mask;
forming a first resist mask, having at least an opening, on said second mask;
etching said second mask to form at least a groove pattern;
forming an etching resistive film as to cover surface of the second mask and inner surfaces of said groove pattern;
etching said etching resistive film as to form side walls in the groove pattern in said second mask;
forming a second resist mask, having at least a via hole pattern, on said second mask, side walls and first mask; and
etching said first mask through said via hole pattern as to form at least a via hole in said multi-layered substrate.

6. The method for fabricating multi-layered wiring structure as claimed in claim 5, wherein said etching resistive film made of material having higher etching resistance than said second mask.
